(19) United States
(12) Patent Application Publication
(10) Pub. No.: US 2001/0046765 A1
(43) Pub. Date: Nov. 29, 2001

(54) Method for producing a barrier layer in an electronic component and method for producing an electronic component with a barrier layer

(76) Inventors: Annalisa Cappellani, Dresden (DE); Dirk Schumann, Dresden (DE); Josef Willer, Riemerling (DE)

Correspondence Address: LERNER AND GREENBERG, P.A., Post Office Box 2480, Hollywook, FL, 33022-2480, US

(21) Appl. No.: 09/850,584

(22) Filed: May 7, 2001

(30) Foreign Application Priority Data
May 5, 2000 (DE) 100 21 871.7

(51) Int. Cl. H01L 21/336; H01L 21/4763; H01L 21/44

(52) U.S. Cl. 438/627; 438/643; 438/653

(57) ABSTRACT

A barrier layer is formed on a substrate layer by implanting implantation atoms into the substrate material of the substrate layer. A metal layer is applied onto the substrate material and the substrate material, the implantation atoms and the metal layer are at least partially brought into reaction with one another in such a way that the barrier layer is formed.

### BACKGROUND OF THE INVENTION

1. Field of the Invention

The invention relates to a method for producing a barrier layer in an electronic component and a method for producing an electronic component with a barrier layer.

Such a method is known from the reference by Byung Hak Lee et al., titled “In-situ, Barrier Formation for High Reliable W/barrier/poly-Si Gate Using Denudation of WNₓ on Polycrystalline Si”, IEDM, Technical Digest, San Francisco, 1998.

In the known method, a barrier layer is used in an electronic component. The barrier layer is normally used as a barrier layer between a metal layer and a substrate layer, for example as part of a gate electrode of a field-effect transistor or as part of a formation of an electric contact between insulating layers within an electronic component.

It is known from the reference to apply a barrier layer of tungsten nitride WNₓ to a substrate layer of polysilicon. The application takes place by amorphous sputtering of the tungsten nitride layer onto the polysilicon layer.

The component obtained in this way is subjected to a rapid annealing process at a temperature of about 1000° C. Due to the rapid annealing, a part of the tungsten nitride layer reacts in such a way that a very thin barrier layer of approximately 2 nm thickness deposits on the surface of the polysilicon layer.

The barrier layer is made of an alloy of tungsten, nitride and silicon, that is a layer of WₓN_{y}Si_{z} forms. The alloy of WₓN_{y}Si_{z} serves as the barrier layer against the layer of tungsten W forming above the barrier layer and prevents a silicidization of the tungsten through the barrier layer.

This known strategy has several disadvantages.

It is costly to apply, especially a tungsten nitride layer, by a sputter process onto the polysilicon layer.

A further disadvantage of the strategy is to be seen in the fact that, due to the sputtering, a particle formation arises which is undesirable in view of the ever-shrinking dimensions of electronic components.

A silicidization using cobalt as a metal is further known from the reference by Wein-Town Sun et al., titled “Mechanism of Improved Thermal Stability of Cobalt Silicide Formed on Polysilicon Gate by Nitrogen Implantation”, Jpn. J. Appl. Phys., Vol. 37, Part 1, No. 11, S. 5954-5860, November 1998, wherein a layer of cobalt silicide is formed on a layer of polysilicon. In this way, the electrical conductivity of the polysilicon layer is reduced since the cobalt silicide has an increased electrical conductivity as compared to polysilicon.

Further processes for the silicidization are described in the references by M. Delfino et al., titled “Formation of TiN/TiSi2/p⁺-Si/n-Si by Rapid Thermal Annealing (RTA) Silicon Implanted with Boron through Titanium”, IEEE Electron Device Letters, Vol. EDL-6, No. 11, S. 591-593, November 1985, by Eiji Nagasawa et al., titled “Mo-Silicided and Ti-Silicided Low-Resistance Shallow Junctions Formed Using the Ion Implantation Through Metal Technique”, IEEE Transactions on Electron Devices, Vol. ED-34, No. 3, S. 581-586, March 1987, and U.S. Pat. No. 5,648,287.

### SUMMARY OF THE INVENTION

It is accordingly an object of the invention to provide a method for producing a barrier layer in an electronic component and a method for producing an electronic component with a barrier layer, which overcomes the above-mentioned disadvantages of the prior art methods of this general type, which method is simpler, cheaper and more quickly performable than the known methods.

With the foregoing and other objects in view there is provided, in accordance with the invention, a method for producing a barrier layer in an electronic component. The method includes the steps of implanting implantation atoms into a substrate material of the electronic component for forming the barrier layer; applying a metal layer to the substrate material; and bringing the substrate material, the implantation atoms, and the metal layer at least partially into reaction with one another such that the barrier layer is formed. A silicidization of the metal layer through the barrier layer is prevented by the barrier layer.

In the method for producing the barrier layer in the electronic component, implantation atoms serving in the formation of the barrier layer are implanted into the substrate material. The metal layer is applied to the substrate material and the substrate material, the implantation atoms and the metal layer are at least partially brought into reaction with one another in such a way that the barrier layer is formed.

Silicon, gallium arsenide or germanium can for example be used as the substrate material.

Nitrogen atoms or boron atoms are for example suitable as implantation atoms.

In the case that boron atoms are used, it is for example possible to generate a p⁺-doped gate electrode of a field-effect transistor.

The substrate material, the implantation atoms as well as the metal layer can be brought into reaction with one another for example by rapid annealing at a temperature of approximately 1000° C., so that an alloy serving as the barrier layer is formed between the substrate material, the implantation atom and the metal layer. Silicidization of the metal layer through the barrier layer is prevented by the barrier layer. In other words, the term “barrier layer” is to be understood in this context as a layer by which a silicidization of a metal layer disposed over the barrier layer is prevented.

The implantation of the implantation atoms can be accomplished in various ways.

It is possible to implant the implantation atoms directly into the substrate material.

Alternatively, a metal layer can be applied onto the substrate material and the implantation of the atoms can be accomplished through the metal layer in a border region of the substrate material and the metal layer.

According to a further embodiment of he invention, it is further possible to apply an oxide layer serving as a scatter oxide layer onto the substrate material, for example by a CVD process, a plasma-enhanced CVD (PECVD) process or a physical vapor deposition (PVD) process. Alternatively, a nitride layer, for example a layer of silicon nitride, can be applied to the substrate material in lieu of the scatter oxide.

The implantation can be accomplished through the scatter oxide, so that a doping profile of the implantation atoms in a border region of the substrate layer and the scatter oxide layer is formed.

In this case, the scatter oxide layer is removed following implantation, for example by a wet etching process, a dry etching process or by a chemical mechanical polishing (CMP) process, and the metal layer is applied to the substrate layer bearing the implantation atoms.

It should further be noted that the implantation can be carried out on both an already structured layer and an unstructured layer, that is with a layer extending over the entire surface of the substrate layer, the metal layer or the scatter oxide layer.

The scatter oxide layer can contain silicon oxide.

Furthermore, the metal layer can contain at least one of the following metals: tungsten, molybdenum, tantalum, rhenium, titanium, zirconium, hafnium, niobium and/or ruthenium.

An electronic component, particularly a field-effect transistor, is formed such that the electronic component is produced according to known process step, wherein the formation of the barrier layer in the electronic component is formed according to the method described above.

In particular, a MOS-field-effect transistor can be manufactured, wherein, according to the process described above, the barrier layer is produced between the canal region of the MOS-field-effect transistor and the metal layer, itself serving as the gate-connection.

The metal layer, which is chemically “shielded” from the substrate material by the barrier layer, can also be used as an electrical contact in an electronic component.

A significant simplification in the production process of the barrier layer as compared to the prior art is now achieved by the simple process of implanting of implantation atoms, since now, costly mechanisms for the sputtering of the barrier layer can be dispensed with. The particle formation caused by the sputtering is also avoided.

Furthermore, the implantation easily allows a very exact adjustment of the implantation profile, that is the tuning of the distribution of the implantation atoms in the substrate layer and/or in the metal layer.

It should further be noted that, although the application of the tungsten nitride WNₓ is possible by a CVD process, a titanium nitride layer TiNₓ or tantalum nitride TaNₓ, both of which can also fundamentally be used in the formation of the barrier layer, cannot easily be applied according to the prior art using a CVD process.

The invention allows circumvention of the problem, namely that various metals that can be used for the metal layer cannot be applied to the substrate material using a sputter process or a CVD process.

By coupling the implantation process and the annealing to form the barrier layer, the annealing step, which is required anyway in a typical production process for field-effect transistors, is simultaneously exploited for the formation of the barrier layer.

The invention thereby ensures in particular a substantial flexibility in the production process of the electronic component since in particular the implantation at various process steps and in various production processes can be performed very easily and flexibly.

Other features which are considered as characteristic for the invention are set forth in the appended claims.

Although the invention is illustrated and described herein as embodied in a method for producing a barrier layer in an electronic component and a method for producing an electroinic component with a barrier layer, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIGS. 1a to 1g are diagrammatic sectional views showing different processing states of a component during a production method according to a first embodiment of the invention;

FIGS. 2a to 2e are sectional views of different processing states of the component during the production method according to a second embodiment;

FIGS. 3a to 3c are sectional views of different processing states of the component during the production method according to a third embodiment.

### DESCRIPTION OF THE PREFERRED EMBODIMENTS

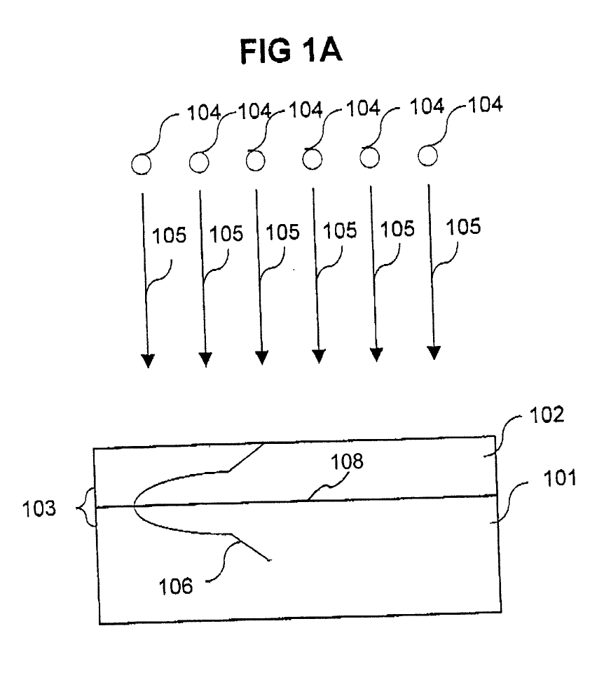

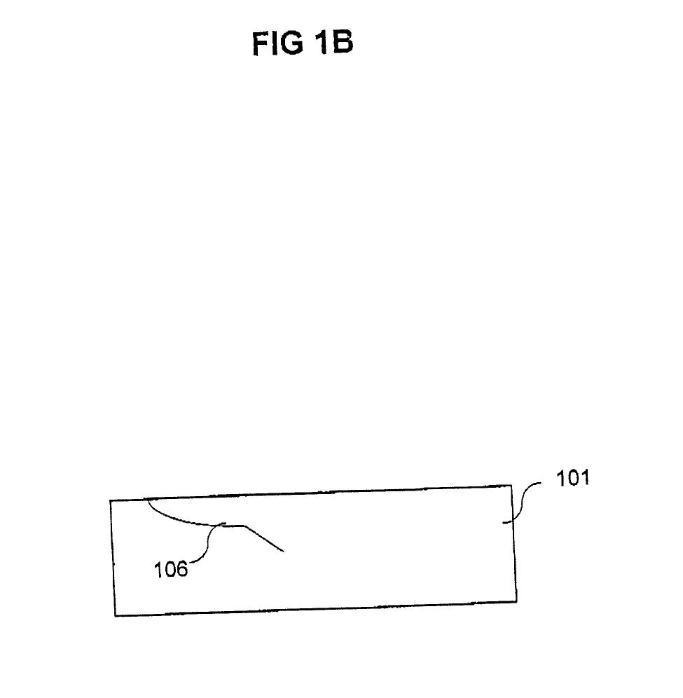

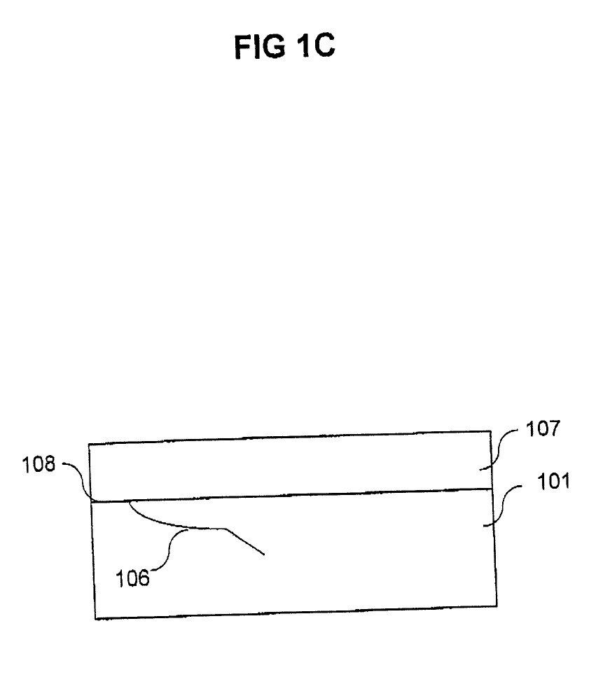

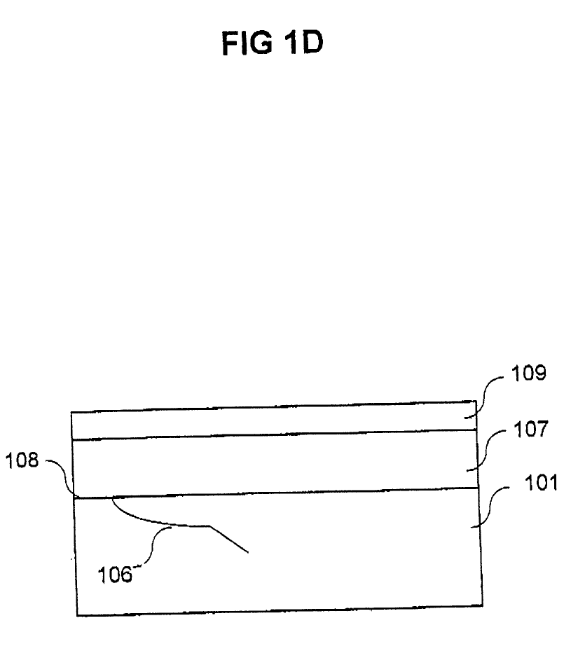

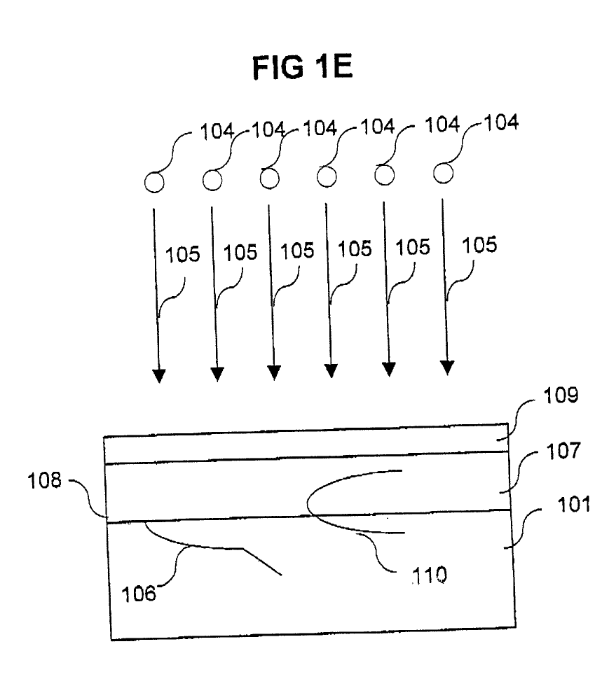

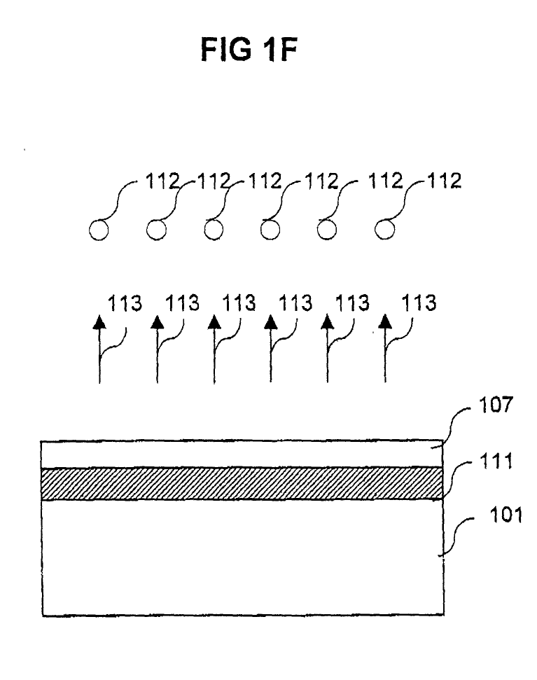

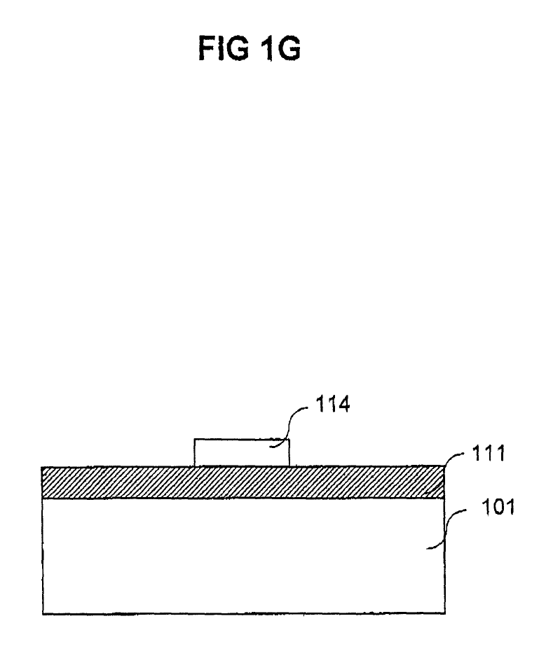

In all the figures of the drawing, sub-features and integral parts that correspond to one another bear the same reference symbol in each case. Referring now to the figures of the drawing in detail and first, particularly, to FIG. 1 thereof, there is shown a substrate layer 101 of silicon or polysilicon, on which a scatter oxide layer 102 made of silicon oxide is deposited by a chemical vapor deposition (CVD) process or a plasma enhanced chemical vapor deposition (PECVD) process.

A TEOS layer of approximately 65 nm thickness can be used as the scatter oxide layer 102.

Nitrogen atoms 104 are implanted in a border region 103 between the substrate layer 101 and the scatter oxide layer 102 by an implantation process at an implantation voltage of approximately 20 keV. The implantation of the nitrogen atoms 104 is symbolized in FIG. 1a by arrows 105.

In order to avoid that too weak an implantation voltage is required for implanting the nitrogen atoms 104, the scatter oxide layer 102 is used. Alternatively, a scatter nitride layer of silicon nitride can be provided in lieu of the scatter oxide layer.

The scatter oxide layer 102 has a thickness of approximately 65 nm.

The dose of the implanted nitrogen atoms 104 is chosen to be large enough that, for example, a nitrogen concentration of 5*10¹⁵ nitrogen atoms/cm² is achieved on a surface 108 of the substrate layer 101.

As shown in FIG. 1a, a first implantation profile 106 is yielded after the implantation.

In a further step (see FIG. 1b), the scatter oxide layer 102 is removed by a dry etch process, a wet etch process or by a chemical mechanical process (CMP), so that the substrate layer 101 doped with the nitrogen atoms 104 remains intact.

As shown in FIG. 1c, a metal layer 107 is applied to the substrate layer 101 with the implanted nitrogen atoms 104 according to the embodiment using a CVD process.

According to the embodiment, the metal layer 107 is made of tungsten.

In applying the metal layer 107 onto the substrate layer 101, it is important inter alia to pay special attention to the connection region between the metal layer 107 and the substrate layer 101.

In particular, one has to pay special attention that a diffusion of the metal atoms of the metal layer 107 into the substrate layer 101 is avoided.

Furthermore, one must make sure that the metal layer 107 physically adheres well to the surface 108 of the substrate layer 101. It has been experimentally demonstrated that good adhesion of, for example, a tungsten layer as a metal layer 107 deposited by a CVD process can easily be achieved by omitting the nucleation step of the silicon seeding in the CVD-tungsten deposition, that is to say that the nucleation step of the silicon seeding is skipped.

In this case, the deposition can take place using tungsten fluoride WF₆ and hydrogen H₂ as the only process gases.

In a further step (see FIG. 1d), a second scatter oxide layer 109 is applied to the metal layer 107.

It should be noted in this context that, within the scope of the invention, the provision of scatter oxide layers or scatter nitride layers is not necessarily mandatory.

In a further layer (see FIG. 1e), the resulting structure is subjected to a further nitrogen atom implantation, that is a further implantation of the nitrogen atoms 104, symbolized by the arrows 105 in FIG. 1e, such that a second doping profile 110 as shown in FIG. 1e results. The thus resulting second doping profile 110 shows that the nitrogen atoms 104 are contained in the second implantation both in the metal layer 107 as well as in the substrate layer 101.

In a further step, the second scatter oxide layer 109 is removed by a dry etch process, a wet etch process or by a CMP process (see FIG. 1f).

The unit of the substrate layer 101 and the metal layer 107 formed in this way and doped with the nitrogen atoms 104 is subjected to a rapid annealing process at a temperature of approximately 1000° C.

A barrier layer 111 is formed between the substrate layer 101 and metal layer 107 by the annealing.

This is achieved by reaction of the implanted nitrogen atoms 104 with the tungsten of the metal layer 107 and the silicon or polysilicon of the substrate layer 101, so that a barrier layer 111 of alloy WSiN results.

In total, one thus obtains for the electronic component, for example a gate structure of a MOS-field-effect transistor, a structure of silicon or polysilicon/the tungsten-silicon-nitrogen metal alloy/and the metal tungsten.

The structure obtained in this manner can be used for example as a gate electrode of a MOS-field-effect transistor or also as an electric connection of a source, a drain or a substrate in a MOS-field-effect transistor.

Nitrogen atoms 112 which do not react during the annealing and the formation of the barrier layer 111 escape from the structure, which is symbolized by arrows 113 in FIG. 1f.

FIG. 1g shows a doped metal layer 114 as arises following a given masking and structuring of the metal layer 107.

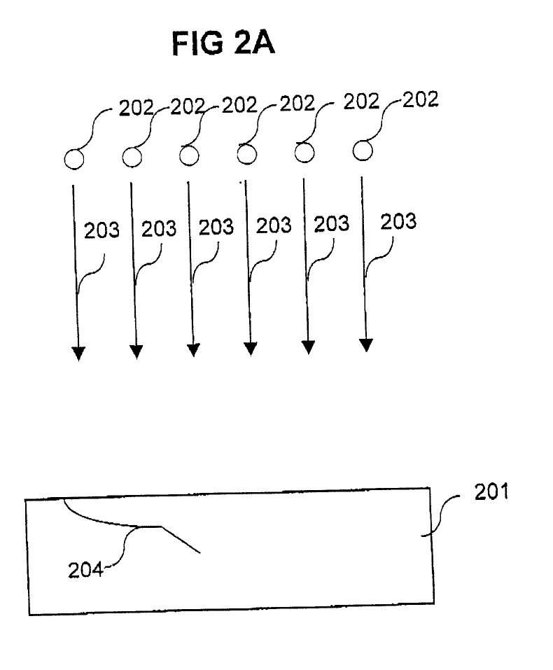

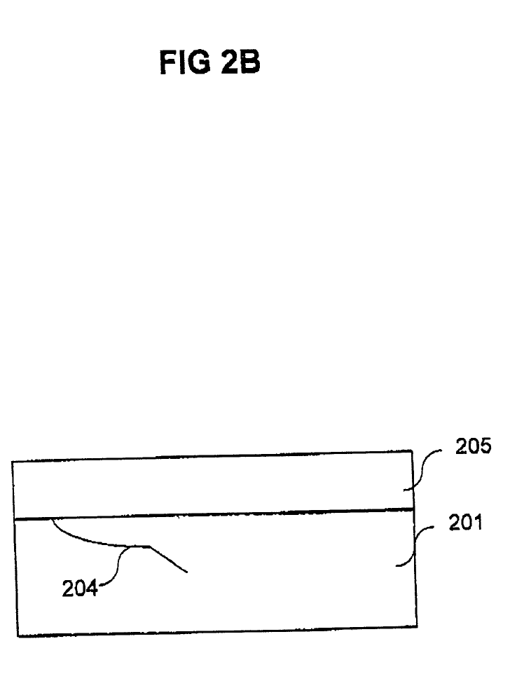

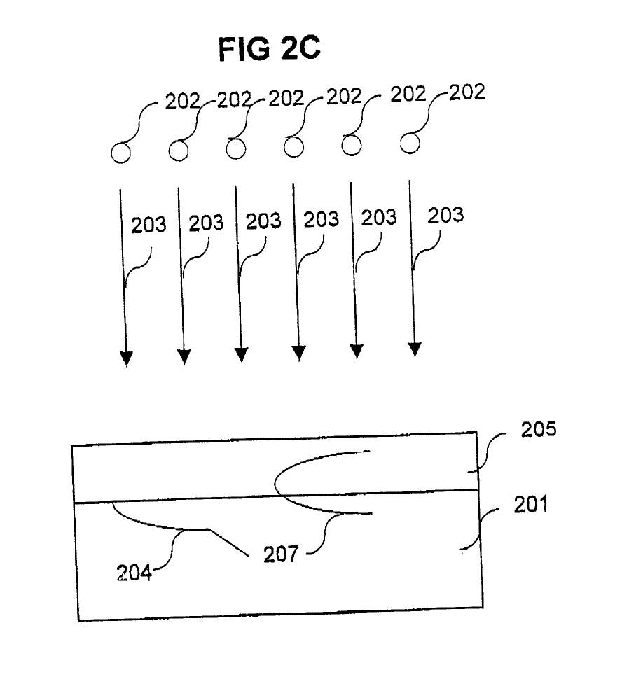

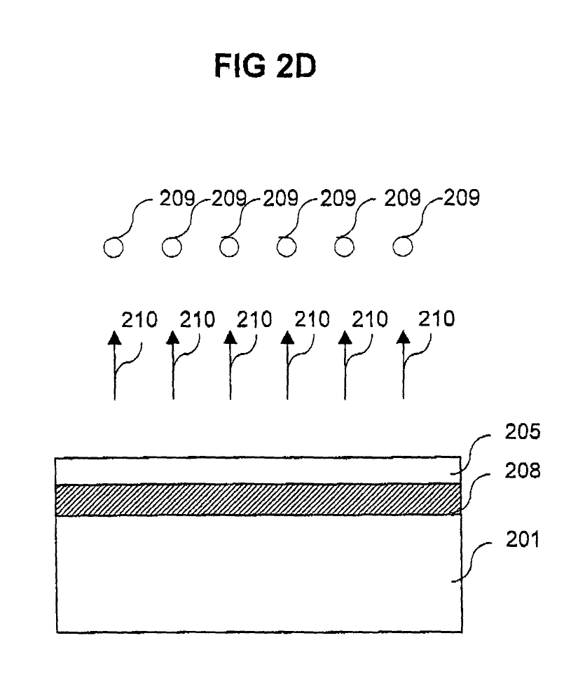

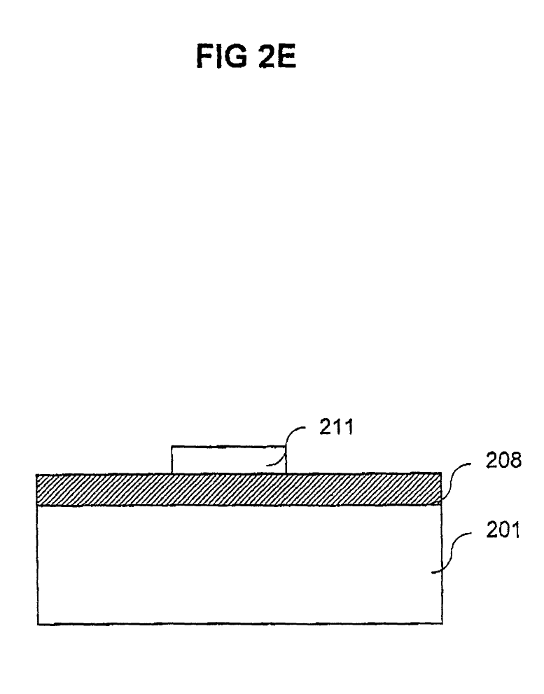

A second embodiment of the invention is shown in FIGS. 2a to FIG. 2e.

According to the second embodiment, one starts with a silicon layer as a substrate layer 201, in which nitrogen atoms 202 are directly implanted, symbolized in FIG. 2a by arrows 203, without provision of a scatter oxide layer as in the first embodiment.

A doping profile 204 thus arises in the substrate layer 201.

In this case, the implantation takes place at an implantation voltage of approximately 10 keV. The implantation voltage according to the second embodiment is chosen to be less, since the scatter oxide layer or the metal layer does not have to be penetrated by the nitrogen atoms in order to get to the substrate layer 201.

A metal layer 205 is deposited on the substrate layer 201 by a CVD process (see FIG. 2b).

As is shown in FIG. 2c, a second implantation of nitrogen atoms 202 into the metal layer 205 and into the silicon layer 201 subsequently takes place.

This is once again symbolized in FIG. 2c by arrows 203.

A second implantation profile 207 therefore arises, which shows that the implantation atoms, that is the nitrogen atoms 202 according to the second embodiment, are contained in both the metal layer 205 and the substrate layer 201.

As according to the first embodiment, a rapid annealing process is carried out on the resulting structure, by which the barrier layer 208 is formed and herein non-reacting nitrogen atoms 209 escape, symbolized by arrows 210 (see FIG. 2d).

FIG. 2e shows the structured metal layer 211 in the resulting structure according to the second embodiment.

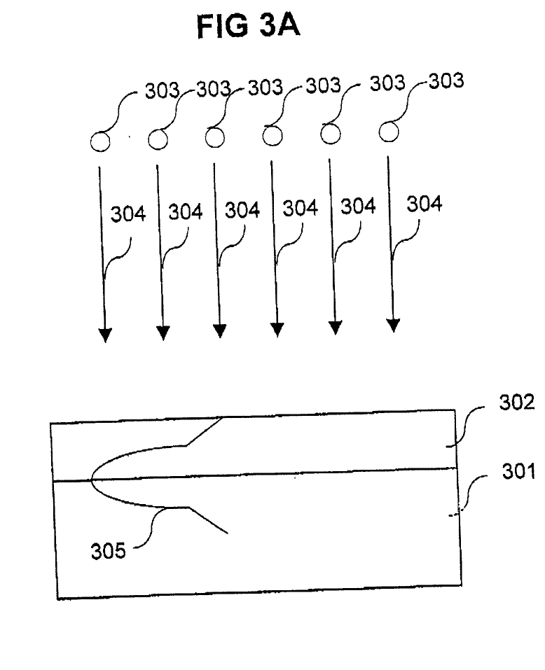

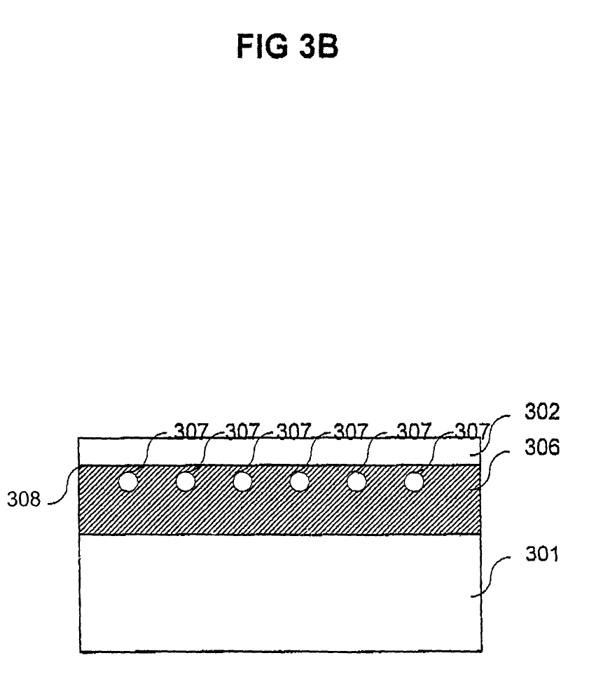

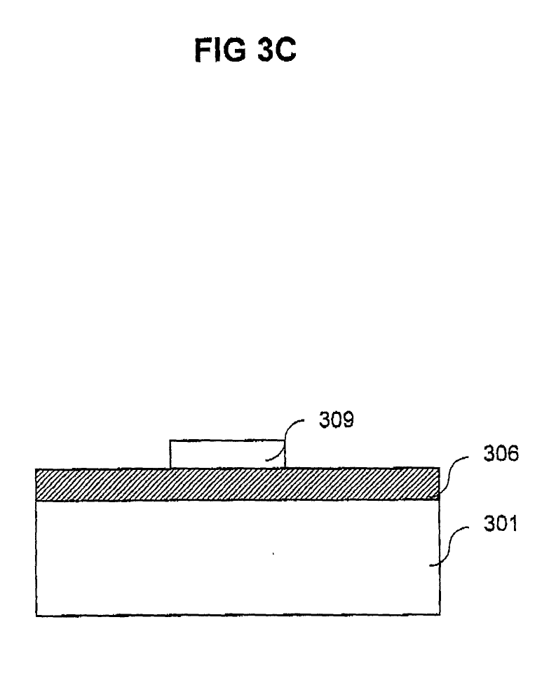

FIG. 3a to FIG. 3c show different process states of a production process of an electronic component or of the barrier layer of the electronic component according to a third embodiment.

According to the third embodiment, one starts with a silicon layer or a polysilicon layer as a substrate layer 301 and a metal layer 302 deposited thereon, for example by a CVD process.

According to the third embodiment, boron atoms 303 are implanted as implantation atoms 303 into the metal layer 302 as well as into substrate layer 301, symbolized in FIG. 3a by arrows 304.

A doping profile 305 thus results in the metal layer 302 and in the substrate layer 301, by which doping profile 305 it is shown that the implanted boron atoms 302 are located in both the metal layer 302 and the substrate layer 301.

In a further annealing process step, the structure obtained in this way is subjected according to the third embodiment to a rapid annealing process at a temperature of approximately 1000° C., whereby a barrier layer 306 is formed, fundamentally according to the method as has been described in the context of the first embodiment (see FIG. 3b).

The barrier layer 306 made of an alloy of silicon/boron/tungsten thus results.

FIG. 3b further shows that, during the formation of the barrier layer 306 at an interface 308 of the barrier layer 306, the latter is enriched with non-reacting boron atoms 307, which is why a silicon/boron/tungsten layer enriched with boron is formed in a border region close to the interface 308.

FIG. 3c further shows the structured metal layer 309 as can be formed by corresponding photolithographic technology.

We claim:

1. A method for producing a barrier layer in an electronic component, which comprises the steps of:
implanting implantation atoms into a substrate material of the electronic component for forming the barrier layer;
applying a metal layer to the substrate material; and
bringing the substrate material, the implantation atoms, and the metal layer at least partially into reaction with one another such that the barrier layer is formed, and a silicidization of the metal layer through the barrier layer is prevented by the barrier layer.

2. The method according to claim 1, which comprises using atoms selected from the group consisting of nitrogen atoms and boron atoms as the implantation atoms.

3. The method according to claim 1, which comprises forming the substrate material from a material selected from the group consisting of silicon, gallium arsenide, and germanium.

4. The method according to claim 1, which comprises performing an annealing of the substrate material, the implantation atoms and the metal layer for bring the substrate material, the implantation atoms and the metal layer at least partially into reaction with one another.

5. The method according to claim 1, which comprises performing the implanting of the implantation atoms after the metal layer has been applied onto the substrate material.

6. The method according to claim 1, which comprises applying a scatter oxide layer onto one of the substrate material and the metal layer, and the implanting of the implantation atoms takes place through the scatter oxide layer.

7. The method according to claim 6, which comprises forming the scatter oxide layer from silicon oxide.

8. The method according to claim 1, which comprises forming the metal layer from at least one material selected from the group consisting of tungsten, molybdenum, tantalum, rhenium, titanium, zirconium, hafnium, niobium, and ruthenium.

9. A production method, which comprises the steps of:
producing an electronic component having a barrier layer by the steps of:
providing a substrate material; implanting implantation atoms into the substrate material for forming the barrier layer;
applying a metal layer to the substrate material; and
bringing the substrate material, the implantation atoms, and the metal layer at least partially into reaction with one another such that the barrier layer is formed, and a silicidization of the metal layer through the barrier layer is prevented by the barrier layer.

10. The method according to claim 9, which comprises:
forming the electronic component as a transistor; and
forming a gate of the transistor from the metal layer.

11. The method according to claim 9, which comprises forming an electrical contact in the electronic component from the metal layer.
